(19) United States
(12) Patent Application Publication
(10) Pub. No.: US 2016/0260924 A1
(43) Pub. Date: Sep. 8, 2016

(54) ORGANIC LIGHT EMITTING DIODE DISPLAY AND METHOD OF MANUFACTURNG THE SAME

(71) Applicant: SAMSUNG DISPLAY CO., LTD, YONGIN-CITY (KR)

(72) Inventors: Yong Su LEE, Seoul (KR); Hye Hyang PARK, Yongin-si (KR); Eun Hyun KIM, Suwon-si (KR)

(21) Appl. No.: 15/002,139

(22) Filed: Jan. 20, 2016

(30) Foreign Application Priority Data
Mar. 2, 2015 (KR) 10-2015-0029335

(51) Int. Cl. H01L 51/52; H01L 51/00; H01L 51/56

(52) U.S. Cl. CPC H01L 51/5237; H01L 51/56; H01L 51/5206; H01L 51/5221; H01L 51/0026; H01L 51/0023

(57) ABSTRACT

An organic light emitting display device according to an exemplary embodiment includes a substrate; a gate electrode formed on the substrate; a gate insulating layer formed on the substrate and covering the gate electrode; a semiconductor layer formed on the gate insulating layer; an etch stopper formed on the semiconductor layer; a passivation layer formed on the semiconductor layer and covering the etch stopper; an interlayer insulating layer formed on the passivation layer; source/drain electrodes formed on the interlayer insulating layer and not overlapping the etch stopper; a planarization layer formed on the interlayer insulating layer and covering the source/drain electrodes; an anode formed on the planarization layer so as to be connected with the drain electrode; a pixel defining layer formed on the planarization layer to partially cover the anode; an organic emission layer formed on the anode; a cathode formed on the organic emission layer and the pixel defining layer; and a sealing member formed on the cathode.

### CLAIM OF PRIORITY

This application claims the priority to and all the benefits accruing under 35 U.S.C. §119 of Korean Patent Application No. 10-2015-0029335 filed in the Korean Intellectual Property Office (KIPO) on Mar. 2, 2015, the entire contents of which are incorporated herein by reference.

### BACKGROUND OF THE INVENTION

1. Field of Disclosure

The described technology relates generally to an organic light emitting display device including a thin film transistor having an etch stopper structure, and a manufacturing method thereof.

2. Description of the Related Art

An organic light emitting display device includes organic light emitting elements formed of a hole injection electrode, an organic emission layer, and an electrode injection electrode. When the anode and cathode inject holes and electrons respectively into the organic light emitting layer, the OLEDs emit light using energy generated when excitons generated by electron-hole combinations in the organic light emitting layer are dropped from an excited state to a ground state, and an image is then displayed.

Since the organic light emitting diode display has a self-luminance characteristic and does not require a separate light source, unlike a liquid crystal display device, it is possible to reduce the thickness and weight thereof. Further, the organic light emitting diode display has high-quality characteristics, such as low power consumption, high luminance, and high response speed.

Recently, an organic light emitting display device includes an oxide thin film transistor in which an active layer is formed by an oxide semiconductor, and in this case, when the oxide semiconductor is applied to an existing bottom-gate structure thin film transistor, the oxide semiconductor may be damaged during an etching process of source/drain electrodes, particularly during a dry-etching process using plasma so that the oxide semiconductor may be degenerated. In order to prevent the degeneration of the oxide semiconductor, an etch stopper is additionally provided as a barrier layer above the active layer. However, the existing structure is different from a top-gate structure in that a channel length of the active layer is relatively longer and the lengths of source/drain areas are differently patterned so that a process margin should be provided in the etch stopper, and accordingly, parasitic electric capacitance between the gate electrode and the source/drain electrodes is increased, thereby deteriorating driving speed of the element.

The above information disclosed in this Background section is only to enhance the understanding of the background of the invention, and therefore it may contain information that does not form the prior art that is already known in this country to a person of ordinary skill in the art.

### SUMMARY OF THE INVENTION

Exemplary embodiments have been made in an effort to provide an organic light emitting display device in which a bottom-gate type thin film transistor structure has an etch stopper that does not overlap source/drain regions and the etch stopper is formed using a halftone mask, thereby reducing the number of mask processes, and a method for manufacturing the same.

An organic light emitting display device according to an exemplary embodiment includes: a substrate; a gate electrode formed on the substrate; a gate insulating layer formed on the substrate and covering the gate electrode; a semiconductor layer formed on the gate insulating layer; an etch stopper formed on the semiconductor layer; a passivation layer formed on the semiconductor layer and covering the etch stopper; an interlayer insulating layer formed on the passivation layer; source/drain electrodes formed on the interlayer insulating layer and not overlapping the etch stopper; a planarization layer formed on the interlayer insulating layer and covering the source/drain electrodes; an anode formed on the planarization layer so as to be connected with the drain electrode; a pixel defining layer formed on the planarization layer to partially cover the anode; an organic emission layer formed on the anode; a cathode formed on the organic emission layer and the pixel defining layer; and a sealing member formed on the cathode.

The etch stopper may be formed corresponding to a location of the gate electrode on the semiconductor layer.

The etch stopper may be formed to be 2 μm to 3 μm in size.

The semiconductor layer may include a gate area formed at a location corresponding to the etch stopper.

The source electrode and the drain electrode may be respectively connected with the source region and the drain region of the semiconductor layer through contact holes formed in the passivation layer and the interlayer insulating layer.

The anode may be connected to the drain electrode through an opening formed in the planarization layer.

The organic light emitting display device may further include a buffer layer provided between the substrate and the gate electrode.

According to an exemplary embodiment, a method for manufacturing an organic light emitting display device is provided. The method includes: forming a gate electrode on a substrate; forming a gate insulating layer on the substrate to cover the gate electrode; forming a semiconductor layer on the gate insulating layer; forming an etch stopper on the semiconductor layer; forming source/drain regions in the semiconductor layer; forming a passivation layer on the semiconductor layer to cover the etch stopper; forming an interlayer insulating layer on the passivation layer; forming contact holes in the passivation layer and the interlayer insulating layer, and forming source/drain electrodes connected with the source/drain regions, not to be overlapped with the etch stopper; forming a planarization layer on the interlayer insulating layer to cover the source/drain electrodes; forming an opening in the planarization layer and forming an anode, connected with the drain electrode, on the planarization layer; forming a pixel defining layer on the planarization layer to partially cover the anode; forming an organic emission layer on the anode; forming a cathode on the organic emission layer and the pixel defining layer; and forming a sealing member on the cathode.

The forming of the gate electrode may include forming the gate electrode through wet-etching or dry-etching.

The forming of the etch stopper may include forming the etch stopper through exposure and development using a halftone mask.

The forming of the source/drain regions may include doping the semiconductor layer with at least one of baron (B), phosphorous (P), arsenic (As), and nickel (Ni).

The forming of the source/drain regions may include performing thermal treatment on the semiconductor layer at a temperature of 450° C. to 630° C.

The forming the source/drain regions may include performing the thermal treatment in a nitrogen or vacuum atmosphere.

The method may further include forming a buffer layer on the substrate before the forming the gate electrode on the substrate.

According to the exemplary embodiments, a bottom-gate type thin film transistor having an etch stopper that does not overlap source/drain regions is provided so that parasitic electric capacitance can be reduced, and the etch stopper is formed by using a halftone mask so that the number of mask processes can be reduced, thereby simplifying the processes.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is an equivalent circuit diagram of an organic light emitting display device according to an exemplary embodiment.

FIG. 2 is a layout view of a pixel structure in a display panel of the organic light emitting display device according to an exemplary embodiment.

FIG. 3 is a cross-sectional view of the organic light emitting display device of FIG. 2, taken along the line III-III.

FIG. 4 is a flowchart of a manufacturing process of an organic light emitting display device according to an exemplary embodiment.

FIG. 5A to FIG. 5J are cross-sectional views of the manufacturing method of the organic light emitting display device according to an exemplary embodiment.

### DETAILED DESCRIPTION OF THE INVENTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

Further, in the exemplary embodiments, since like reference numerals designate like elements having the same configuration, an exemplary embodiment is representatively described, and in other exemplary embodiments, only configurations that differ from the exemplary embodiment will be described.

It shall be noted that the drawings are schematic and do not depict exact dimensions. The relative proportions and ratios of elements in the drawings may be exaggerated or diminished in size for the sake of clarity and convenience in the drawings, and such arbitrary proportions are only illustrative and not limiting in any way. Like reference numerals are used for like structures, elements, or parts shown in two or more drawings to show similar characteristics. When one part is said to be “over” or “on” another part, the one part may be directly over the other part or there may be another part interposed therebetween.

Exemplary embodiments specifically show preferred exemplary embodiments. As a result, various modifications of the drawings are anticipated. Therefore, the exemplary embodiments are not limited to a specific form of an illustrated region, and for example, may include modifications of a manufactured form.

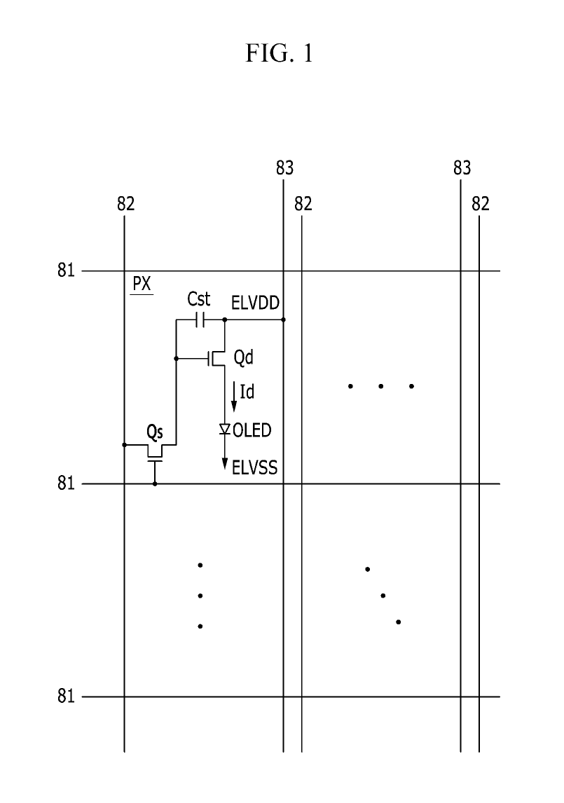

Hereinafter, an organic light emitting display device according to an exemplary embodiment will be described with reference to FIG. 1 to FIG. 3.

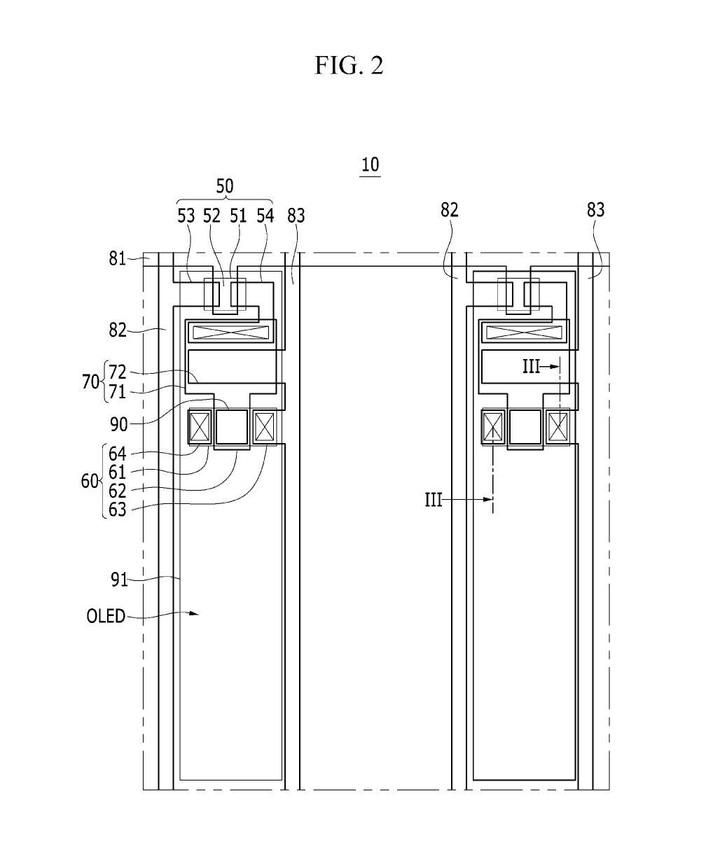

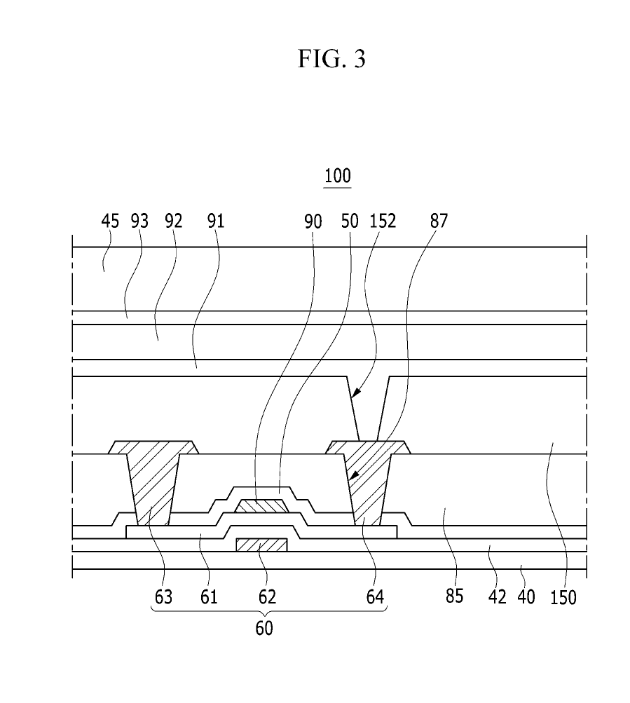

FIG. 1 is an equivalent circuit diagram of an organic light emitting display device according to an exemplary embodiment, FIG. 2 is a layout view of a pixel structure of a display panel in the organic light emitting display device according to such exemplary embodiment, and FIG. 3 is a cross-sectional view of the organic light emitting display device according to such exemplary embodiment.

Referring to FIG. 1, the organic light emitting display device includes a plurality of signal lines 81, 82, and 83 and a plurality of pixels PX connected to the signal lines and substantially arranged in a matrix format.

The signal lines include a plurality of gate lines transmitting a scan signal (or, a gate signal), a plurality of data lines 82 transmitting a data signal, and a plurality of driving voltage lines 83 transmitting a driving voltage. The gate lines 81 are substantially extended in a row direction and practically parallel with each other, and the data lines 82 and the driving voltage lines 83 are substantially extended in a column direction and practically parallel with each other.

Each pixel PX may include a switching thin film transistor Qs, a driving thin film transistor Qd, a storage capacitor Cst, and an organic light emitting diode OLED.

The switching thin film transistor Qs includes a control terminal, an input terminal, and an output terminal, and the control terminal is connected to the gate line 81, the input terminal is connected to the data line 82, and the output terminal is connected to the driving thin film transistor Qd. The switching thin film transistor Qs transmits a data signal applied to the data line 82 to the driving thin film transistor Qd in response to a scan signal applied to the gate line 81.

The driving thin film transistor Qd includes a control terminal, an input terminal, and an output terminal, and the control terminal is connected to the switching thin film transistor Qs, the input terminal is connected to the driving voltage line 83, and the output terminal is connected to the organic light emitting diode (OLED). An output current Id flows from the driving thin film transistor Qd, the intensity of which varies according to a voltage between the control terminal and the output terminal.

The storage capacitor Cst is connected between the control terminal and the input terminal of the driving thin film transistor Qd. The storage capacitor Cst charges a data signal applied to the control terminal of the driving thin film transistor Qd, and maintains the data signal after the switching thin film transistor Qs is turned off.

The organic light emitting diode OLED includes an anode connected to the output terminal of the driving thin film transistor Qd and a cathode connected to a common voltage ELVSS. The organic light emitting diode OLED emits light with intensities that vary according to the output current Id of the driving thin film transistor Qd.

The switching thin film transistor Qs and the driving thin film transistor Qd may be n-channel field effect transistors (FETs). However, at least one of the switching thin film transistor Qs and the driving thin film transistor Qd may be a p-channel field effect transistor. In addition, a connection relationship among the thin film transistors Qs, and Qd, the capacitor Cst, and the organic light emitting diode OLED may be changed.

Referring to FIG. 2, an organic light emitting panel 10 may include a pixel circuit DC and an organic light emitting diode OLED formed in each pixel. The pixel circuit DC basically includes a thin film transistor 60 and a capacitor 70. In addition, the display panel 10 includes a gate line 81 arranged in one direction, a data line 82, and a driving voltage line 83. The data line 82 and the driving voltage line 83 cross the gate line 81 in an insulated manner.

Here, one pixel PX may be defined by the boundary of the gate line 81, the data line 82, and the driving voltage line 83, but it is not restrictive. The pixel PX implies a basic unit displaying an image, and the display panel 10 displays an image using a plurality of pixels PX.

The structure of the display panel 10 is not limited to the drawing. The display panel 10 may be provided with three or more thin film transistors and two or more capacitors, and as a result, may have various structures in which a separate wiring is further formed.

The organic light emitting diode OLED includes a pixel electrode (i.e., an anode 91), an organic emission layer 92, and a common electrode (i.e., a cathode 93). One of the pixel electrode 91 and the common electrode 93 is a hole injection electrode and the other is an electron injection electrode. Electrons and holes from the pixel electrode 91 and the common electrode 93 are injected to the organic emission layer 92, and light is emitted when an exciton formed by coupling the injected holes and electrons with each other falls from an excited state to a ground state.

The pixel electrode 91 may be formed of a highly reflective metal, and the common electrode 93 may be formed of a transparent conductive layer. In this case, light from the organic emission layer 92 is reflected by the pixel electrode 91 and then emitted to the outside through the common electrode 93 and the thin film encapsulation layer 45.

The capacitor 70 includes a pair of capacitor electrodes 71 and 72 arranged to interpose an interlayer insulating layer 85, which is a dielectric material. Charges charged in the capacitor 70 and a voltage between the two capacitor electrodes 71 and 72 determine capacitance.

The driving thin film transistor 60 applies driving power to the pixel electrode 91 for light emission of an organic emission layer 92 of a selected pixel. The driving gate electrode 62 is connected with the capacitor electrode 71. The source electrode 63 and the capacitor electrode 72 are connected with the driving voltage line 83. The drain electrode 64 is connected with the pixel electrode 91 of the organic light emitting diode OLED through a contact hole 87.

Referring to FIG. 3, the organic light emitting display device according to the exemplary embodiment includes a substrate 40, a gate electrode 62 formed above the substrate 40, a gate insulating layer 42 formed above the substrate 40 and covering the gate electrode 62, a semiconductor layer 61 formed above the gate insulating layer 42, an etch stopper 90 formed above the semiconductor layer 61, a passivation layer 50 formed above the semiconductor layer 61 and covering the etch stopper 90, and an interlayer insulating layer 85 formed above the passivation layer 50.

The substrate 40 may be formed of an insulating substrate made of glass, quartz, ceramic, plastic, and the like. However, the present invention is not limited thereto. Thus, the substrate 40 may be formed of a metallic substrate made of stainless steel.

The gate electrode 62 is formed above the substrate 40. The gate electrode 62 may be formed of a single metal, or may be made of one of molybdenum (Mo), titanium (Ti), or tungsten (W). In addition, the gate electrode 62 may be formed by a laminated structure of the inorganic insulating layer and the organic insulating layer.

The gate insulating layer 42 covering the gate electrode 62 is formed above the substrate 40. The gate insulating layer 42 may be made of a ceramic-based material such as silicon nitride (SiNx) or silicon oxide (SiO2) and the like.

The semiconductor layer 61 formed above the gate insulating layer 42 is formed of a polysilicon layer. The semiconductor layer 61 includes a channel region 61a in which an impurity is not doped and a source region 61b and a drain region 61c in which the impurities are doped at both sides of the channel region 61a. In this case, a doped ion material is a P-type impurity, such as baron B, and B2H6 is usually used. Here, the impurity may be changed according to the type of the thin film transistor. That is, the semiconductor layer 61 may be doped with one of baron (B), phosphorous (P), arsenic (As), or nickel (Ni).

A buffer layer may be further provided between the substrate 40 and the gate electrode 62. The buffer layer prevents permeation of an impurity element and provides a flat surface, and it may be made of various materials that can provide such a function. For example, the buffer layer may be one of a silicon nitride (SiNx) layer, a silicon oxide (SiO2) layer, or a silicon oxynitride (SiOxNy) layer. However, the buffer layer is not a required configuration, and may be omitted depending on a kind of substrate 40 and a process condition.

The etch stopper 90 is formed above the semiconductor layer 61. The etch stopper 90 may be formed corresponding to a location of the gate electrode 62 on the semiconductor layer 61, and may be formed to be about 2 μm to about 3 μm in size.

The passivation layer 50 covering the etch stopper 90 is formed above the semiconductor layer 61, and the interlayer insulating layer 85 is formed above the passivation layer 50. The passivation layer 50 may protect metal wires and bridge wires as a protection layer, and may be formed of a single layer which is made of a material such as a silicone oxide layer and a silicon nitride layer or a multilayer thereof, but is not limited thereto, and therefore the passivation layer 50 may be made of various materials.

The interlayer insulating layer 85 includes contact holes 87 exposing the source region 61b and the drain region 61c of the semiconductor layer 61. Like the gate insulating layer 42, the interlayer insulating layer 85 may be made of a ceramic-based material such as silicon nitride (SiNx) or silicon oxide (SiO2).

Meanwhile, a source electrode 62 and a drain electrode 64 that do not overlap the etch stopper 90 are formed on interlayer insulating layer 85. The source electrode 63 and the drain electrode 64 are respectively connected with the source region 61b and the drain region 61c of the semiconductor layer 61 through the contact holes 87 formed in the passivation layer 50 and the interlayer insulating layer 85.

A planarization layer 150 covering the source electrode 63 and the drain electrode 64 is formed on the interlayer insulating layer 85. The planarization layer 150 serves to remove and planarize a step in order to increase emission efficiency of the organic light emitting element to be formed thereon.

The planarization layer 150 may be made of one or more materials of polyacrylates resin, epoxy resin, phenolic resin, polyamides resin, polyimide resin, unsaturated polyester resin, poly phenylenethers resin, poly phenylenesulfides resin, and benzocyclobutene (BCB).

The exemplary embodiment is not limited to the above-stated structure, and one of the planarization layer 150 and the interlayer insulating layer 85 may be omitted as necessary.

The anode 91 of the organic light emitting element is formed on the planarization layer 150. That is, the organic light emitting display device includes a plurality of anodes 91 arranged in each of the plurality of pixels. In this case, the plurality of anodes 91 are disposed at a distance from each other. The anode 91 is connected with the drain electrode 64 through an electrode contact hole of the planarization layer 150.

A pixel defining layer 160 including an opening that exposes the anode 91 is formed on the planarization layer 150. That is, the pixel defining layer 160 includes a plurality of openings formed in each pixel. In addition, the anodes 91 are arranged to correspond to the openings of the pixel defining layer 160. However, the anodes 91 are not arranged only in the openings of the pixel defining layer 160, and the anodes 91 may be provided below the pixel defining layer 160 so as to partially overlap the pixel defining layer 160. The pixel defining layer 160 may be made of a resin, such as a polyacrylate-based resin, and polyimides or a silica-based inorganic material.

The organic emission layer 92 is formed above the anode 91, and the cathode 93 is formed above the organic emission layer 92. As described, an organic light emitting element including the anode 91, the organic emission layer 92, and the cathode 93 is formed.

The organic emission layer 92 is made of a low-molecular material or a high-molecular material. In addition, the organic emission layer 92 may be formed in multiple layers, including an emission layer and one or more of a hole injection layer (HIL), a hole transporting layer (HTL), an electron transporting layer (ETL), and an electron injection layer (EIL). In the case where the organic emission layer 92 includes all of the layers, the hole injection layer (HIL) is disposed on the anode 191, which is an anode, while the hole transporting layer (HTL), the emission layer, the electron transporting layer (ETL), the electron injection layer (EIL) are sequentially laminated thereon.

The organic emission layer 92 is arranged only in the opening of the pixel defining layer 160, but the exemplary embodiment is not limited thereto. Thus, the organic emission layer 92 may be formed not only in the opening of the pixel defining layer 160, but also between the pixel defining layer 160 and the cathode 93. More specifically, the organic emission layer 92 may further include layers such as a hole injection layer (HIL), a hole transport layer (HTL), an electron transport layer (ETL), and an electron injection layer (EIL) together with an emission layer. In this case, like the cathode 93, excluding the emission layer that may be formed above the pixel defining layer 160, the above-stated layers may be formed not only on the anode 91 but also on the pixel defining layer 160 using an open mask during a manufacturing process. That is, one or more layers among the above-stated layers included in the organic emission layer 92 may be disposed between the pixel defining layer 160 and the cathode 93.

The anode 91 and the cathode 93 may be respectively made of a transparent conductive material or a transflective or reflective conductive material. According to the type of materials forming the anode 91 and the cathode 93, the organic light emitting display device may be a top emission type, a bottom emission type, or a double-sided emission type.

As the transparent conductive material, a material such as indium tin oxide (ITO), indium zinc oxide (IZO), zinc oxide (ZnO), or indium oxide (In2O3) may be used. As the reflective or transflective material, lithium (Li), calcium (Ca), lithium fluoride/calcium (LiF/Ca), lithium fluoride/aluminum (LiF/Al), aluminum(Al), silver (Ag), magnesium (Mg), or gold (Au) may be used.

A sealing member 45 is provided above the cathode 93. The sealing member 45 is disposed opposite to the substrate 40. The sealing member 45 may be made of a transparent material such as glass or plastic. The sealing member 45 may be bonded and sealed with the substrate 40 through a sealant formed along the edge thereof.

In addition, the sealing member 45 may be layered to form a thin film encapsulation layer. As a thin film encapsulation layer, at least one organic layer and at least one inorganic layer may be alternately laminated. A plurality of inorganic layers or organic layers may each be laminated. The organic layer is made of polymer, and preferably, may be a single layer or a laminated layer formed by any one of polyethylene terephthalate, polyimide, polycarbonate, epoxy, polyethylene, or polyacrylate. More preferably, the organic layer may be formed of polyacrylate, and more specifically, includes a material in which a monomer composition including diacrylate-based monomers and triacrylate-based monomers is polymerized. Monoacrylate-based monomers may be further included in the monomer composition. In addition, in the monomer composition, a known photoinitiator such as TPO may be further included, but the present invention is not limited thereto.

The inorganic layer may be a single layer or a laminated layer including metal oxide or metal nitride. Specifically, the inorganic layer may include any one of SiNx, Al2O3, SiO2, and TiO2.

A top layer of an encapsulation layer exposed to the outside may be formed as an inorganic layer in order to prevent moisture from penetrating the organic light emitting diode.

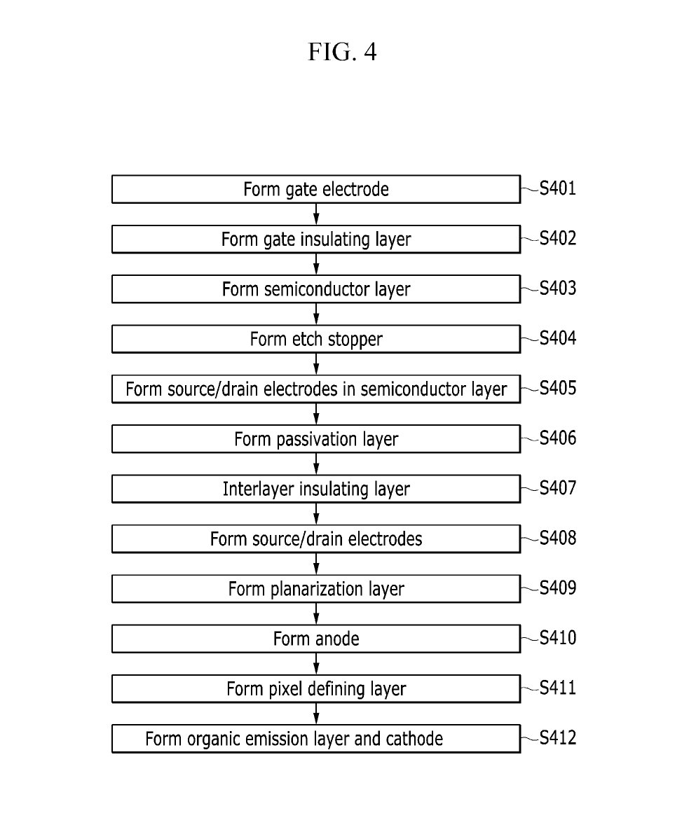

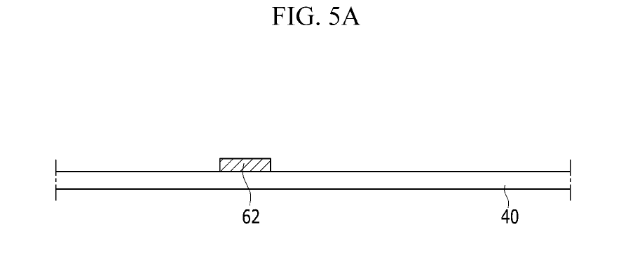

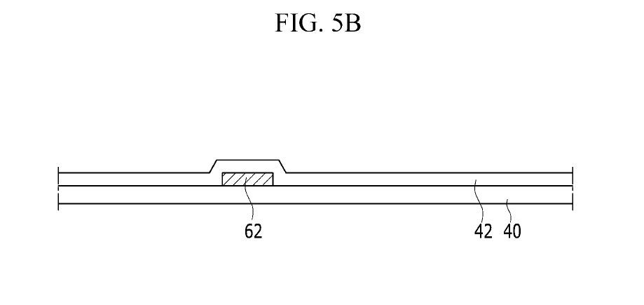

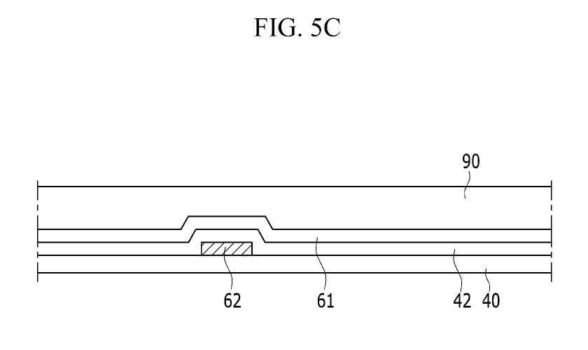

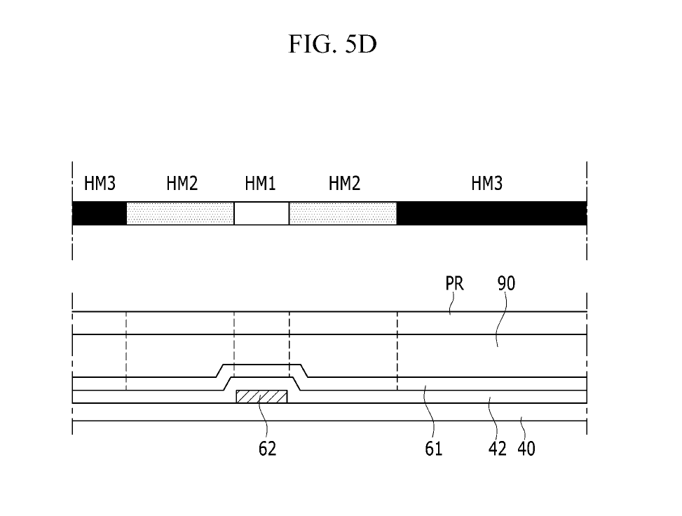

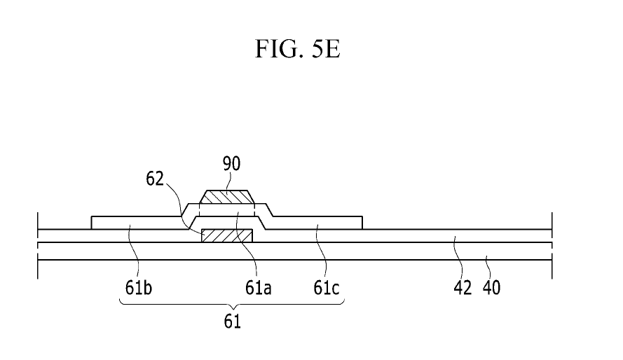

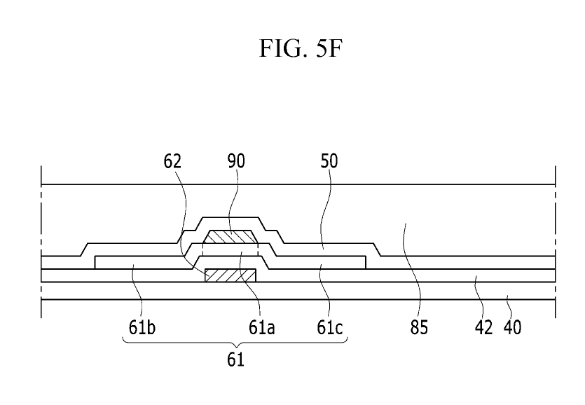

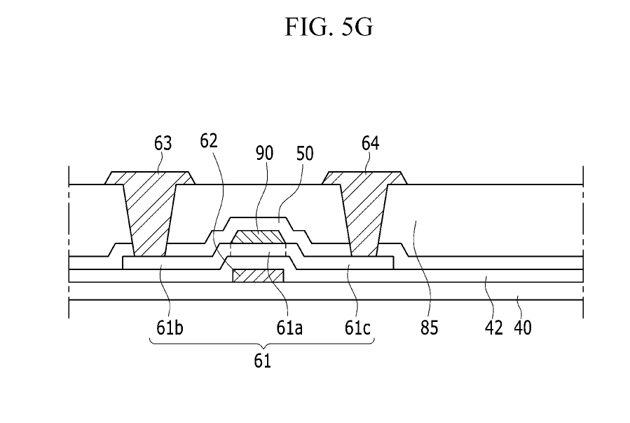

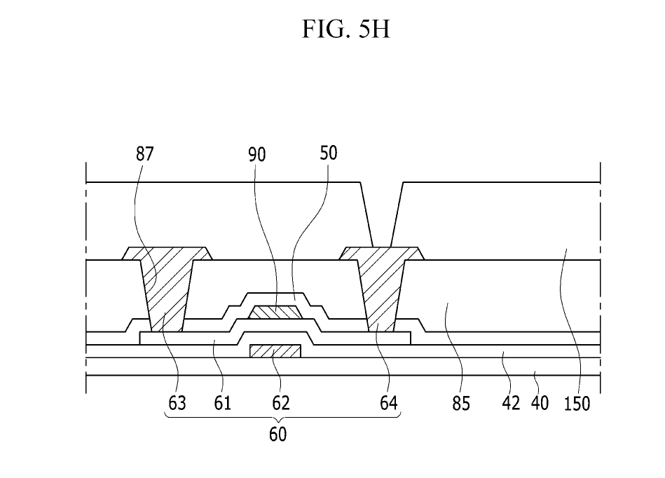

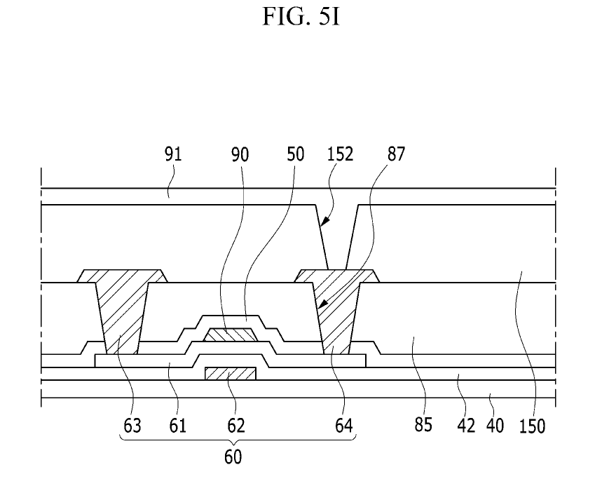

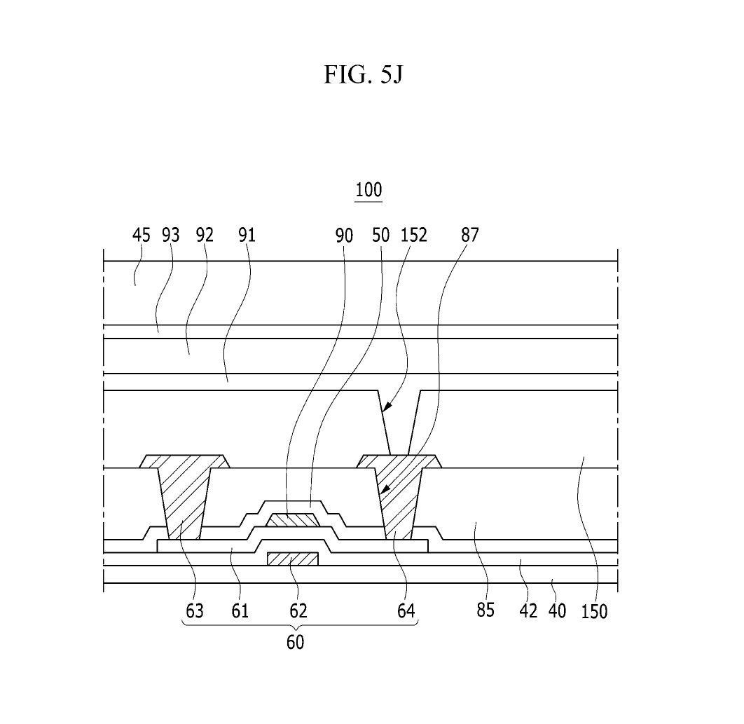

Hereinafter, a method for manufacturing an organic light emitting display device according to an exemplary embodiment will be described with reference to FIG. 4 to FIG. 5J.

FIG. 4 is a flowchart of a manufacturing method of an organic light emitting display device according to an exemplary embodiment, and FIG. 5A to FIG. 5J are cross-sectional views of the manufacturing method of the organic light emitting display device according to an exemplary embodiment.

First, a gate electrode 62 is formed on a substrate 40 (S401, FIG. 5A). The gate electrode 62 may be formed by leaving a portion of a gate electrode material through wet-etching or dry-etching after forming the gate electrode material throughout the substrate 40.

Next, a gate insulating layer 42 is formed on the substrate 40 to cover the gate electrode 62 (S402, FIG. 5B). The gate insulating layer 42 is made of a ceramic-based insulating material such as silicon nitride (SiNx) or silicon oxide (SiO2).

Next, a semiconductor layer 61 is formed on the gate insulating layer 42 (S403, FIG. 5C). In addition, an etch stopper 90 is formed on the semiconductor layer 61 (S404, FIG. 5D). The semiconductor layer 61 and the etch stopper layer 90 are formed throughout the gate insulating layer 42, and the etch stopper layer 90 may be patterned using a halftone mask.

Referring to FIG. 5D, a photo-resist (PR) is coated on the etch stopper layer 90 and then exposed and developed using a halftone mask HM that includes a transmission region HM1, a transflective region HM2, and a blocking region HM3 such that the photo-resist PR in a region where the etch stopper layer 90 is formed becomes thicker than that of other regions where source and drain regions 61b and 61c of the semiconductor layer 61 are formed. Next, the photo-resist PR is etched to leave the photo-resist only in the region where the etch stopper layer 90 is formed. The photo-resist PR that is left is exposed and developed again to remove a portion of the etch stopper layer 90 corresponding to the source and drain regions 61b and 61c such that the etch stopper layer 90 is formed only in a portion corresponding to a channel region 61a (FIG. 5E).

Next, the source region 61b and the drain region 61c are formed in the semiconductor layer 61 (S405, FIG. 5F). A dopant is doped and thermally treated in the semiconductor layer 61. The semiconductor layer 61 includes a channel region 61a in which an impurity is not doped and a source region 61b and a drain region 61c formed at two sides of the channel region, in which p+ are doped. In this case, a doped ion material is a P-type impurity such as baron B, and B2H6 is usually used. Here, the impurity may be changed according to the type of the thin film transistor. That is, the semiconductor layer 61 may be doped with one of baron (B), phosphorous (P), arsenic (As), or nickel (Ni). In this case, the thermal treatment may be formed in a nitrogen or vacuum atmosphere with a temperature of 450° C. to 630° C.

Next, a passivation layer 50 is formed on the semiconductor layer 61 to cover the etch stopper layer 90 (S406), and an interlayer insulating layer 85 is formed on the passivation layer (S407, FIG. 5F).

Next, contact holes are formed in the passivation layer 50 and the interlayer insulating layer 85, and a source electrode 63 and a drain electrode 64 connected with the source/drain regions 61b and 61c are formed on the interlayer insulating layer 85 (S408, FIG. 5G).

Next, a planarization layer 150 is formed on the interlayer insulating layer 85 to cover the source/drain electrodes 63 and 64 (S409, FIG. 5H). The planarization layer 150 serves to eliminate a step for planarization of the surface in order to increase emission efficiency of the organic light emitting element to be formed thereon.

Next, an opening is formed in the planarization layer 150 and an anode 91 connected with the drain electrode 64 is formed on the planarization layer 150 (S410, FIG. 5I). In addition, a pixel defining layer 160 is formed on the planarization layer 150 to partially cover the anode 91 and an organic emission layer 92 is formed on the anode 91, and a cathode 93 is formed on the organic emission layer 92 and the pixel defining layer 160 and then a sealing member is formed on the cathode 93 (S412, FIG. 5J). A sealing member 45 is disposed opposite to the substrate 40. The sealing member 45 may be made of a transparent material such as glass and plastic. The sealing member 45 may be attached and sealed with the substrate 40 through a sealant formed along the edge thereof.

Meanwhile, after the gate electrode 62 is formed on the substrate 40, a buffer layer may be formed on the substrate 40.

As described, in the organic light emitting display device and the manufacturing method thereof according to the exemplary embodiments, a bottom-gate type thin film transistor structure having an etch stopper that does not overlap source/drain regions can be provided so that parasitic electric capacitance can be reduced, and the etch stopper is formed using a halftone mask so that the number of masks can be reduced, thereby simplifying the process.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

### DESCRIPTION OF SYMBOLS

40: substrate
42: gate insulating layer
61: semiconductor layer
62: gate electrode
63: source electrode
64: drain electrode
60: thin film transistor
50: passivation layer
85: interlayer insulating layer
87: contact hole
90: etch stopper
91: anode
150: planarization layer
160: pixel defining layer
92: organic emission layer
93: cathode
45: sealing member

What is claimed is:

1. An organic light emitting display device comprising:
a substrate;
a gate electrode formed on the substrate;
a gate insulating layer formed on the substrate and covering the gate electrode;
a semiconductor layer formed on the gate insulating layer;
an etch stopper formed on the semiconductor layer;
a passivation layer formed on the semiconductor layer and covering the etch stopper;
an interlayer insulating layer formed on the passivation layer;
source/drain electrodes formed on the interlayer insulating layer and not overlapping the etch stopper;
a planarization layer formed on the interlayer insulating layer and covering the source/drain electrodes;
an anode formed on the planarization layer so as to be connected with the drain electrode;
a pixel defining layer formed on the planarization layer to partially cover the anode;
an organic emission layer formed on the anode;
a cathode formed on the organic emission layer and the pixel defining layer; and
a sealing member formed on the cathode.

2. The organic light emitting display device of claim 1, wherein the etch stopper is formed corresponding to a location of the gate electrode on the semiconductor layer.

3. The organic light emitting display device of claim 1, wherein the etch stopper is formed to be 2 μm to 3 μm in size.

4. The organic light emitting display device of claim 1, wherein the semiconductor layer comprises a gate area formed at a location corresponding to the etch stopper.

5. The organic light emitting display device of claim 1, wherein the source electrode and the drain electrode are respectively connected with the source region and the drain region of the semiconductor layer through contact holes formed in the passivation layer and the interlayer insulating layer.

6. The organic light emitting display device of claim 1, wherein the anode is connected to the drain electrode through an opening formed in the planarization layer.

7. The organic light emitting display device of claim 1, further comprising a buffer layer provided between the substrate and the gate electrode.

8. A method for forming an organic light emitting display device, comprising:
forming a gate electrode on a substrate;
forming a gate insulating layer on the substrate to cover the gate electrode;
forming a semiconductor layer on the gate insulating layer;
forming an etch stopper on the semiconductor layer;
forming source/drain regions in the semiconductor layer;
forming a passivation layer on the semiconductor layer to cover the etch stopper;
forming an interlayer insulating layer on the passivation layer;
forming contact holes in the passivation layer and the interlayer insulating layer, and forming source/drain electrodes connected with the source/drain regions, not to overlap the etch stopper;
forming a planarization layer on the interlayer insulating layer to cover the source/drain electrodes;
forming an opening in the planarization layer and forming an anode, connected with the drain electrode, on the planarization layer;
forming a pixel defining layer on the planarization layer to partially cover the anode;
forming an organic emission layer on the anode;
forming a cathode on the organic emission layer and the pixel defining layer; and
forming a sealing member on the cathode.

9. The method for manufacturing the organic light emitting display device of claim 8, wherein forming the gate electrode comprises forming the gate electrode through wet-etching or dry-etching.

10. The method for manufacturing the organic light emitting display device of claim 8, wherein forming the etch stopper comprises forming the etch stopper through exposure and development using a halftone mask.

11. The method for manufacturing the organic light emitting display device of claim 8, wherein forming the source/drain regions comprises doping the semiconductor layer with at least one of baron (B), phosphorous (P), arsenic (As), and nickel (Ni).

12. The method for manufacturing the organic light emitting display device of claim 8, wherein forming the source/drain regions comprises performing thermal treatment on the semiconductor layer at a temperature of 450° C. to 630° C.

13. The method for manufacturing the organic light emitting display device of claim 8, wherein forming the source/drain regions comprises performing the thermal treatment in a nitrogen or vacuum atmosphere.

14. The method for manufacturing the organic light emitting display device of claim 8, further comprising, prior to forming the gate electrode on the substrate, forming a buffer layer on the substrate.
